(19) United States
(12) Patent Application Publication
(10) Pub. No.: US 2011/0052923 A1
(43) Pub. Date: Mar. 3, 2011

(54) METHOD OF PRODUCING EPITAXIAL WAFER AS WELL AS EPITAXIAL WAFER

(75) Inventors: Shigeru Umeno, Tokyo (JP); Toshiaki Ono, Tokyo (JP); Wataru Sugimura, Tokyo (JP)

(73) Assignee: SUMCO CORPORATION, Tokyo (JP)

(21) Appl. No.: 12/862,126

(22) Filed: Aug. 24, 2010

(30) Foreign Application Priority Data
Sep. 3, 2009 (JP) 2009-203435

(51) Int. Cl. H01B 1/04; C30B 15/00; B32B 9/00

(52) U.S. Cl. 428/446; 117/35; 252/500

(57) ABSTRACT

An epitaxial wafer is produced by a method comprising steps of growing a silicon single crystal ingot having a given oxygen concentration through Czochralski method, cutting out a wafer from the silicon single crystal ingot, subjecting the wafer to a heat treatment at a given temperature for a given time, and epitaxially growing the wafer.

### BACKGROUND OF THE INVENTION

1. Field of the Invention

This invention relates to a method of producing a silicon single crystal wafer, and more especially to a method of producing a silicon single crystal wafer grown through Czochralski method (CZ method) and preferably used as a substrate for a semiconductor device. Moreover, this invention relates to an epitaxial wafer having high-density oxygen precipitation nuclei just beneath an epitaxial layer and being preferably used as a substrate for a semiconductor device.

2. Description of the Related Art

The silicon single crystal grown through the CZ method includes void defects generally referred to as COP (crystal originated particles). It is known that the COP deteriorates a gate oxide integrity since it accelerates thinning of the gate oxide film.

Also, since supersaturated oxygen is soluted in the silicon single crystal grown through the CZ method, the supersaturated oxygen is precipitated as SiO₂ in a device production step. The precipitation of oxygen outside an active region of the device exerts an effect that contaminated metal is absorbed (gettering) to prevent metal contamination in the active layer of the device. However, the precipitation of oxygen in the active region adjacent to the surface of the device exerts a bad influence on device properties.

In order to avoid the above problem, there is produced a wafer in which silicon is epitaxially grown on a polished surface of a silicon wafer. The epitaxially grown layer does not contain COP nor excessive oxygen, and is thus most suitable as an active layer of the device.

However, since the epitaxial growth is generally conducted by rapidly raising a temperature to not lower than 1100° C. through lamp heating, oxygen precipitation nuclei existing in the wafer disappear. Thus, sufficient oxygen precipitation is not caused in the recent device process with a lower temperature, so that the gettering ability is lacking, and in many cases the metal contamination of the active layer in the device cannot be prevented effectively.

On the other hand, when oxygen precipitates are existent on the surface portion of the wafer in the production of epitaxial wafers, there is a problem that stacking faults (epitaxial defects) are caused in the resulting epitaxial layer due to oxygen precipitates on the surface portion and the latter half of the crystal cannot be used, lowering the yield.

For this reason, as described in JP-A-H07-22429, a silicon wafer used for an epitaxial wafer is generally used to have an oxygen concentration of 12×10″ to 14×10¹⁷ atoms/cm³. Most of users' specifications are set in such a range.

Recently, it is demanded by users to further improve the gettering ability. As a typical technique of improving the gettering ability, there are proposed a pre-annealing method in which a silicon wafer is subjected to a heat treatment for the formation of oxygen precipitation nuclei or a heat treatment for the growth of oxygen precipitates before epitaxial growth processing so as to preliminarily increase the oxygen precipitate density in the silicon wafer as described in JP-A-H03-50186, and a nitrogen-doping method in which nitrogen is added into the wafer to form thermally stable oxygen precipitation nuclei in the crystal in the growth of silicon single crystal ingot to thereby suppress disappearance of the oxygen precipitates through a heat treatment in the epitaxial processing as described in JP-A-2000-272995.

In the above pre-annealing method, the oxygen concentration is low, which can reduce the occurrence of epitaxial defects due to oxygen precipitates, but the proximity gettering effect is low and an epitaxial wafer having sufficient oxygen precipitates cannot be produced.

In the above nitrogen-doping method, an epitaxial wafer having an oxygen precipitate density to some extent can be obtained, but there is a problem that epitaxial defects due to nitrogen or oxygen precipitates easily occur. Moreover, there is a problem that the scattering of the oxygen precipitate density is caused in a length direction of the single crystal ingot due to the segregation of nitrogen concentration.

Of course, the epitaxial wafer after the production is subjected to a device production process. In this case, since sintering subjected to the wafer is generally a heat treatment at a low temperature of not more than 500° C., interstitial oxygen atoms in the wafer form a composite, which is a donor.

In nature, desired resistivity and conductivity type are controlled by adding an impurity such as boron, phosphorus or the like during the growth of a crystal or by implanting ions to a wafer in the device production process. However, there is caused a disadvantage that the resistivity is changed by the oxygen donor.

Thus, it is necessary to conduct an adequate heat treatment in the wafer production process so as to suppress the change of the resistivity as much as possible.

### SUMMARY OF THE INVENTION

It is, therefore, an object of the invention to provide an epitaxial wafer having an excellent gettering ability, particularly a wafer having an increased density of oxygen precipitates (BMD) in a bulk region just beneath an epitaxial layer. Further, it is another object of the invention to provide an epitaxial wafer in which the occurrence of epitaxial defects in an epitaxial layer is suppressed. In addition, it is the other object of the invention to provide an epitaxial wafer being less in the variation of resistivity.

In order to solve the above problems, the inventors have made various studies without sticking to the common belief that epitaxial defects occur as the oxygen concentration in the wafer becomes too high and investigated production conditions causing no disadvantage even when it is first essential to increase the oxygen concentration in the wafer, and as a result, there is obtained a new knowledge that, as long as a heat treatment is conducted under certain pre-annealing conditions before epitaxial growth, even when using a wafer with excessively increased oxygen concentration, it is possible to obtain an epitaxial wafer causing no epitaxial defect and being excellent in the gettering ability and low in the occurrence of thermal donor.

The summary and construction of the invention for solving the problems are as follows:

(1) A method of producing an epitaxial wafer comprising

a step of growing a silicon single crystal ingot having an oxygen concentration of 18×10¹⁷ to 21×10¹⁷ atoms/cm³ through Czochralski method;

a step of cutting out a wafer from the silicon single crystal ingot;

a step of subjecting the cut silicon wafer to a heat treatment at a temperature of 750° C. to 850° C. for not less than 20 minutes but not more than 50 minutes; and

a step of epitaxially growing the silicon wafer.

(2) An epitaxial wafer containing oxygen precipitation nuclei of not less than 1×10⁹/cm³ within a depth of 10 μm just beneath an epitaxial layer.

(3) A semiconductor device comprising an epitaxial wafer as described in the item (2).

(4) A semiconductor wafer comprising a single crystal silicon wafer having an oxygen concentration of 18×10¹⁷ to 21×10¹⁷ atoms/cm³ and an epitaxial layer formed on a surface of the single crystal silicon wafer.

(5) A semiconductor device comprising a single crystal silicon wafer having an oxygen concentration of 18×10¹⁷ to 21×10¹⁷ atoms/cm³, an epitaxial layer formed on a surface of the single crystal silicon wafer and a semiconductor element formed on a surface of the epitaxial layer.

According to the method of the invention, even when using a single crystal silicon wafer having a significantly high interstitial oxygen concentration of 18×10¹⁷ to 21×10¹⁷ atoms/cm³ as measured by FT-IR method (ASTM F121-79), it is possible to provide heat treating conditions capable of providing an epitaxial wafer without the problem of gettering ability, the epitaxial defects and the variation of resistivity.

Therefore, the epitaxial wafer obtained according to the method of the invention has an oxygen precipitation nuclei of not less than 1×10⁹/cm³ within a depth of 10 μm just beneath the epitaxial layer, which has not been seen in the conventional wafer, and is excellent in the gettering ability.

### BRIEF DESCRIPTION OF THE DRAWINGS

FIG. 1-1 is a graph showing the number of epitaxial defects under each condition;

FIG. 1-2 is a graph showing the number of epitaxial defects under each condition;

FIG. 1-3 is a graph showing the number of epitaxial defects under each condition;

FIG. 1-4 is a graph showing the number of epitaxial defects under each condition;

FIG. 1-5 is a graph showing the number of epitaxial defects under each condition;

FIG. 2 is a graph showing a BMD density after heat treatment simulating device process;

FIG. 3 is a graph showing an increase of resistivity due to oxygen donor;

FIG. 4 is a graph showing the number of epitaxial defects, oxygen precipitate density just beneath epitaxial layer and resistivity under each condition of temperatures; and

FIG. 5 is a graph showing the number of epitaxial defects, oxygen precipitate density just beneath epitaxial layer and resistivity under each condition of heat treating times.

### DESCRIPTION OF THE PREFERRED EMBODIMENTS

The experimental results leading to the invention will be described in detail below.

First, it is necessary to increase an oxygen concentration itself of a wafer to be epitaxially grown up to a higher level exceeding the conventional common wisdom in order to provide an epitaxial wafer having a high gettering ability demanded particularly recently. Based on this, the inventors have made various studies on conditions enabling to use a wafer with a high oxygen concentration as follows.

The oxygen concentration in a silicon single crystal is determined by three factors of (1) melting of quartz into a silicon melt, (2) transferring of a melt and (3) evaporation from a melt surface.

In the experiments of the invention, quartz rings with different sizes are placed on a bottom of a quartz crucible, and polycrystalline silicon materials are filled thereon and then melted under heating. By placing the quartz rings in the quartz crucible is increased a contact area between melt and quartz, whereby an amount of quartz melted into a silicon melt can be increased. With respect to the transferring of the melt, it is desirable that the melt having a high oxygen concentration is raised up toward a solid interface, so that it is better not to apply a magnetic field having an effect of suppressing convection of the melt. Further, in order to suppress evaporation from a melt surface, it is effective that the ratio of (diameter of silicon single crystal)/(inner diameter of quartz crucible) is increased to reduce a free surface area of the melt. Moreover, it is also effective to set a pressure inside the furnace at a higher level. By adjusting plural factors as mentioned above can be grown a silicon single crystal having the desired oxygen concentration.

In this way, there are pulled up 7 silicon single crystals of 310 mm in diameter, whose oxygen concentrations are about 15×10¹⁷ atoms/cm³, 16×10¹⁷ atoms/cm³, 18×10¹⁷ atoms/cm³, 19×10¹⁷ atoms/cm³, 21×10¹⁷ atoms/cm³, 22×10¹⁷ atoms/cm³ and 23×10¹⁷ atoms/cm³, respectively. The oxygen concentration used herein is a value measured through FT-IR method (ASTM F121-79). After these single crystals are rounded to a diameter of 300 mm by cylindrical grinding, a wafer is cut out therefrom, etched to remove processing strain and further washed to remove contaminated substances. Thereafter, the silicon wafer of an as-grown state is subjected to a heat treatment at a temperature of 650° C., 700° C., 800° C. or 900° C. for a heat treating time of 30 minutes, 50 minutes, 60 minutes, 80 minutes or 200 minutes. All of these wafers are p-type and have a resistivity of 10 Ω·cm. These wafers are mirror-finished, and thereafter an epitaxial layer having a thickness of 10 μm is formed thereon at 1100° C. as a sample. The reason why the thickness of the epitaxial layer is made as thick as 10 μm as compared with the common thickness of not more than 5 μm for a 300 mm wafer is due to the fact that epitaxial defects can be detected more easily.

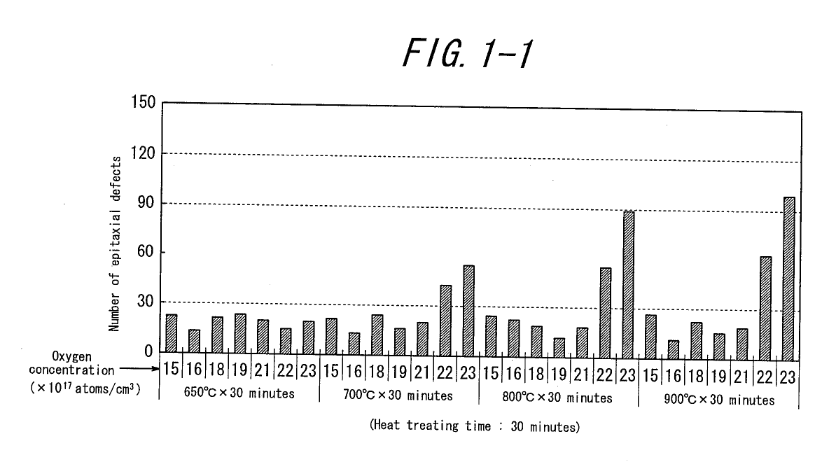

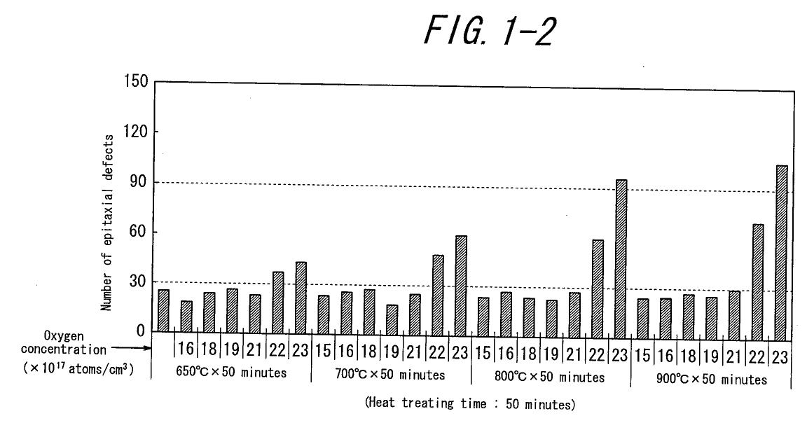

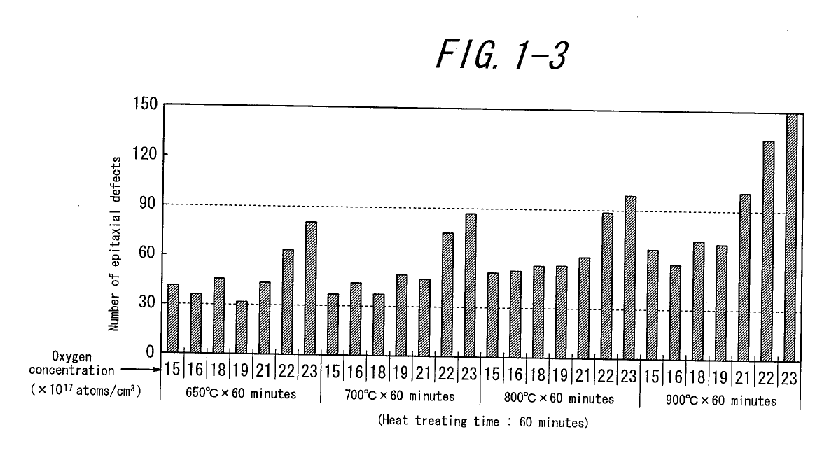

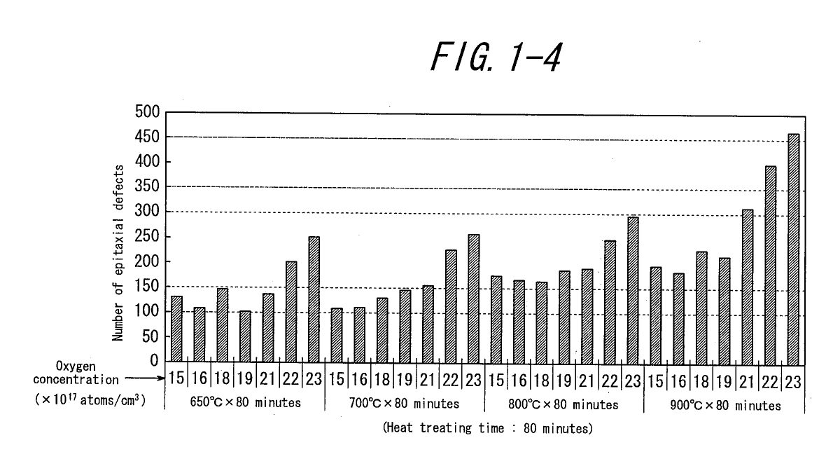

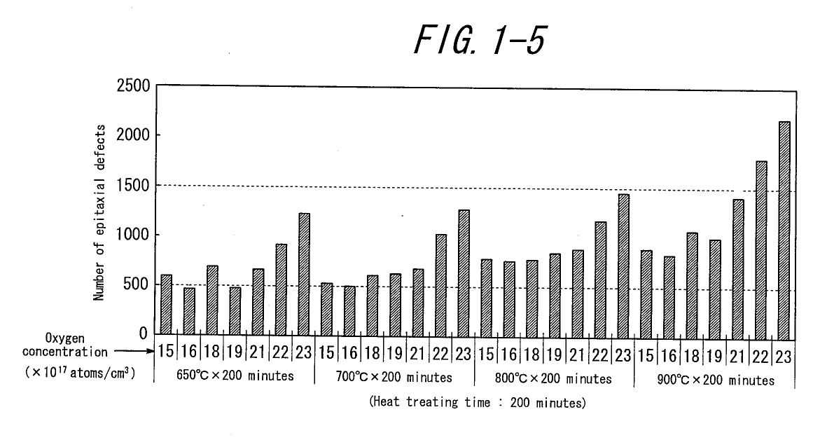

With respect to the above epitaxial wafers are evaluated epitaxial defects using SURFSCAN (registered trademark) SP1 made by KLA-Tencor Corporation. The results measured on the number of defects having a normal particle conversion size of not less than 90 nm are shown in FIGS. 1-1 to 1-5. In these figures, a horizontal axis indicates conditions of heat treatment conducted before epitaxial growth and oxygen concentration of the sample. As seen from FIGS. 1-1 to 1-5, epitaxial defects are increased when the heat treating time is not less than 60 minutes. Therefore, it is revealed that a short heat treating time of not more than 50 minutes is suitable when the oxygen concentration is as high as 15×10¹⁷ atoms/cm³ to 23×10¹⁷ atoms/cm³.

Moreover, when the oxygen concentration is not less than 22×10¹⁷ atoms/cm³ in the heat treating time of not more than 50 minutes, epitaxial defects are increased, which shows that the upper limit of oxygen concentration is 21×10¹⁷ atoms/cm³ in the invention.

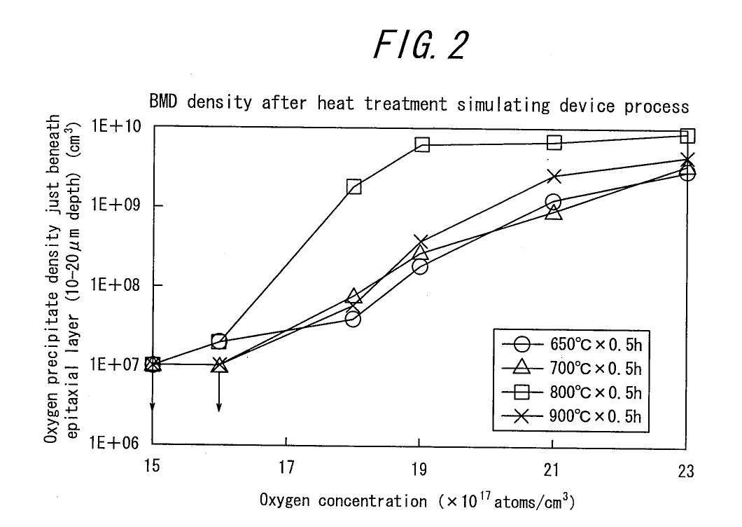

Next, the epitaxial wafers pre-annealed for 30 minutes are subjected to heat treatment in 6 stages from a lowest temperature of 800° C. to a highest temperature of 1000° C. for 23 hours in total as a heat treatment simulating the production process of a device made from a 300 mm wafer, and then to heat treatment at 450° C. for 1 hour assuming the sintering process. FIG. 2 shows results on oxygen precipitate density just beneath the epitaxial layer (10 to 20 μm depth) as measured with BMD analyzer MO441 made by Raytex Corporation. Since the oxygen precipitate density is desirable to be not less than 1×10⁹/cm³ in the light of the gettering ability, the lower limit of oxygen concentration is considered to be about 18×10¹⁷ atoms/cm³. Moreover, it is revealed that the heat treating temperature before epitaxial growth is most preferable to be 800° C. among 4 experiments.

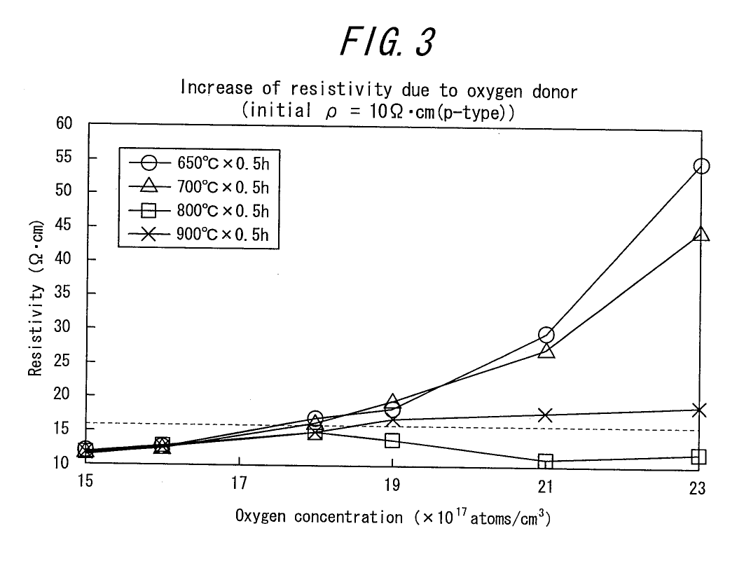

Finally, FIG. 3 shows results measured on the resistivity of the sample subjected to the heat treatment simulating the production process of the above device by the four-point probe method. In this case, oxygen donor is generated by the heat treatment of 450° C. for 1 hour assuming the sintering process, and the resistivity is higher than the initial value of 10 Ω·cm at any levels. The specification of the resistivity of the device simulating the heat treatment in the production process is 10 to 16 Ω·cm, which is shown by a dashed line in FIG. 3. From FIG. 3, it is also revealed that the heat treating temperature before epitaxial growth is most preferable to be 800° C. among 4 experiments in the light of suppressing the variation of resistivity due to oxygen donor.

Moreover, the same experiments as mentioned above are conducted when the pre-annealing time is set to be 50 minutes. As a result, the heat treating temperature is most preferable to be 800° C. likewise the case with pre-annealing time of 30 minutes in the light of both gettering ability and suppression of the variation of resistivity.

The method of producing an epitaxial wafer according to the invention is based on such a technical knowledge, and characterized in that a silicon single crystal having an oxygen concentration of 18×10¹⁷ atoms/cm³ to 21×10¹⁷ atoms/cm³ is pulled up by Czochralski method, and a wafer is cut out from this crystal and subjected to a heat treatment at about 800° C. for a short time of not more than 50 minutes, and then epitaxial growth is conducted after mirror-polishing.

According to the invention, there can be produced an epitaxial wafer suppressing the occurrence of epitaxial defects, providing the gettering ability just beneath the epitaxial layer and suppressing the variation of resistivity due to oxygen donor. Moreover, there is no problem that the latter half of crystal cannot be used as in the nitrogen-doped crystal, and further the production cost can be reduced because of the short heat treating time.

According to the invention, it is possible to provide an epitaxial wafer having oxygen precipitation nuclei of not less than 1×10⁹/cm³ within a depth of 10 μm just beneath the epitaxial layer. However, the density of oxygen precipitation nuclei is not more than 1×10¹¹/cm³ since the wafer is easily cracked in the device process when the density of oxygen precipitation nuclei is too high.

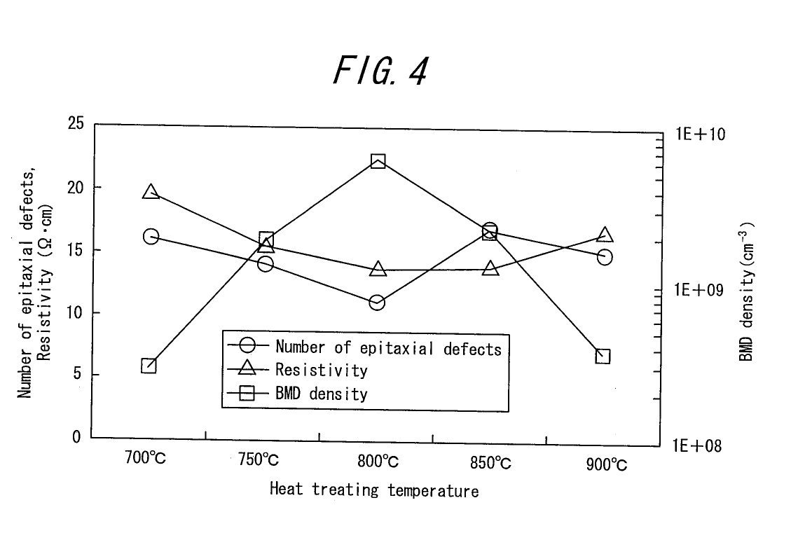

Next, in order to determine preferable temperature conditions in more detail, silicon wafers having an oxygen concentration of 19×10¹⁷ atoms/cm³ are subjected to a heat treatment at 700° C., 750° C., 800° C., 850° C. and 900° C. for 30 minutes, respectively, mirror-polished and epitaxially grown to a thickness of 10 μm to evaluate epitaxial defects, oxygen precipitate density just beneath the epitaxial layer after the heat treatment simulating the device process and variation of resistivity due to oxygen donor generated through the heat treatment simulating the device process. FIG. 4 shows the number of epitaxial defects, the oxygen precipitate density just beneath the epitaxial layer and the resistivity relative to each temperature condition. According to FIG. 4, the number of epitaxial defects is nearly constant from 700° C. to 900° C. The oxygen precipitate density just beneath the epitaxial layer is highest at 800° C., and not less than 1×10⁹/cm³ from 750° C. to 850° C. The resistivity is not more than 16 Ω·cm from 750° C. to 850° C.

Thus, it is found that the heat treating temperature is preferable to be 750° C. to 850° C. in terms of providing the gettering ability and suppressing the variation of resistivity.

The same experiments as mentioned above are conducted for the heat treating time of 20 minutes or 50 minutes without changing other conditions, and as the result, it is found that the preferable heat treating temperature is also 750° C. to 850° C. in terms of epitaxial defects, oxygen precipitate density and the variation of resistivity.

Even when the same experiment is conducted at the oxygen concentration of 18×10¹⁷ atoms/cm³ or 21×10¹⁷ atoms/cm³ without changing other conditions, the preferable heat treating temperature is 750° C. to 850° C. in terms of epitaxial defects, oxygen precipitate density and the variation of resistivity.

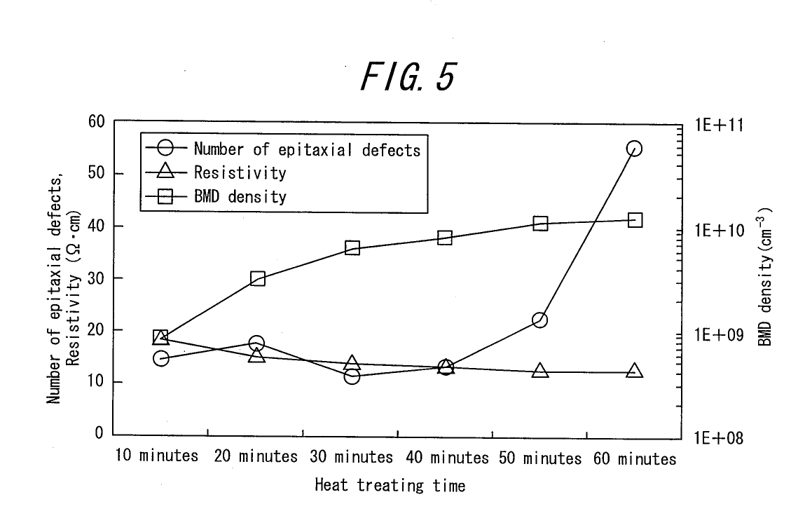

Next, in order to determine preferable heat treating time conditions in detail, silicon wafers having an oxygen concentration of 19×10¹⁷ atoms/cm³ are subjected to heat treatment at 800° C. for 10 minutes, 20 minute, 30 minutes, 40 minutes, 50 minutes and 60 minutes, respectively, and mirror-polished and epitaxially grown to a thickness of 10 μm to evaluate epitaxial defects, oxygen precipitate density just beneath the epitaxial layer after the heat treatment simulating the device process and variation of resistivity due to oxygen donor generated through the heat treatment simulating the device process. FIG. 5 shows the number of epitaxial defects, the oxygen precipitate density just beneath the epitaxial layer and the resistivity relative to each temperature condition. According to FIG. 5, the number of epitaxial defects is nearly constant from 10 minutes to 50 minutes and is increased at 60 minutes, and hence the upper limit of the heat treating time should be 50 minutes (as already described by comparison between FIG. 1-2 and FIG. 1-3). The oxygen precipitate density just beneath the epitaxial layer is not less than 1×10⁹/cm³ except a case of 10 minutes, and hence the lower limit of the heat treating time should be 20 minutes. Since the resistivity is not more than 16 Ω·cm in a case of not less than 20 minutes, the lower limit of the heat treating time is also to be 20 minutes.

From the above, it is revealed that the heat treating time is preferably 20 minutes to 50 minutes in the light of the provision of the gettering ability and the suppression of the variation of resistivity.

Even when the same experiment is conducted at the oxygen concentration of 18×10¹⁷ atoms/cm³ or 21×10¹⁷ atoms/cm³ without changing other conditions, the preferable heat treating time is 20 minutes to 50 minutes in terms of epitaxial defects, oxygen precipitate density and the variation of resistivity.

The same experiment is conducted at the heat treating temperature of 750° C. or 850° C. without changing other conditions, and as a result, it is found that the preferable heat treating time is also 20 minutes to 50 minutes in terms of epitaxial defects, oxygen precipitate density and the variation of resistivity.

As mentioned above, according to a more preferable embodiment of the invention, a silicon single crystal having an oxygen concentration of 18×10¹⁷ atoms/cm³ to 21×10¹⁷ atoms/cm³ is pulled up through the Czochralski method, and a wafer is cut out from this crystal and subjected to a heat treatment at a temperature of 750° C. to 850° C. for 20 minutes to 50 minutes, and then epitaxial growth is conducted after the minor-polishing.

Although preferred examples of the invention have been described above, it is clear that the invention is not limited to the above examples and various modifications can be made without departing from the spirit of the invention and such modifications are also encompassed in the scope of the invention.

According to the invention, there can be produced an epitaxial wafer suppressing the occurrence of epitaxial defects, providing the gettering ability just beneath the epitaxial layer and suppressing the variation of resistivity due to oxygen donor. Moreover, there is no problem that the latter half of crystal cannot be used as in the nitrogen-doped crystal, and further the production cost can be reduced because of the short heat treating time.

What is claimed is:

1. A method of producing an epitaxial wafer comprising
a step of growing a silicon single crystal ingot having an oxygen concentration of 18×10¹⁷ to 21×10¹⁷ atoms/cm³ through Czochralski method;
a step of cutting out a wafer from the silicon single crystal ingot;
a step of subjecting the cut silicon wafer to a heat treatment at a temperature of 750° C. to 850° C. for not less than 20 minutes but not more than 50 minutes; and
a step of epitaxially growing the silicon wafer.

2. An epitaxial wafer containing oxygen precipitation nuclei of not less than 1×10⁹/cm³ within a depth of 10 μm just beneath an epitaxial layer.

3. A semiconductor device comprising an epitaxial wafer as claimed in claim 2.

4. A semiconductor wafer comprising a single crystal silicon wafer having an oxygen concentration of 18×10¹⁷ to 21×10¹⁷ atoms/cm³ and an epitaxial layer formed on a surface of the single crystal silicon wafer.

5. A semiconductor device comprising a single crystal silicon wafer having an oxygen concentration of 18×10¹⁷ to 21×10¹⁷ atoms/cm³, an epitaxial layer formed on a surface of the single crystal silicon wafer and a semiconductor element formed on a surface of the epitaxial layer.
